(19) United States
(12) Patent Application Publication
(10) Pub. No.: US 2011/0174607 A1
(43) Pub. Date: Jul. 21, 2011

(54) COLORED DEVICE CASING AND SURFACE-TREATING METHOD FOR FABRICATING SAME

(75) Inventors: GA-LANE CHEN, Santa Clara, CA (US); CHAO-TSANG WEI, Tu-Cheng (TW); CHUNG-PEI WANG, Tu-Cheng (TW); CHING-CHOU CHANG, Tu-Cheng (TW); SHIH-CHE CHIEN, Tu-Cheng (TW); WEI-CHENG LING, Tu-Cheng (TW); CHIA-YING WU, Tu-Cheng (TW); HSIN-CHIN HUNG, Tu-Cheng (TW); MING-YANG LIAO, Tu-Cheng (TW); TAI-SHENG TSAI, Tu-Cheng (TW); CHIEN-HAO HUANG, Tu-Cheng (TW)

(73) Assignee: HON HAI PRECISION INDUSTRY CO., LTD., Tu-Cheng (TW)

(21) Appl. No.: 12/839,353

(22) Filed: Jul. 19, 2010

(30) Foreign Application Priority Data
Jan. 19, 2010 (TW) 99101298

(51) Int. Cl. C23C 14/02; B32B 15/01

(52) U.S. Cl. 204/192.1; 428/172

(57) ABSTRACT

A colored device casing includes a base, a color layer and a bonding layer. The base has at least one smooth region. The bonding layer is positioned between the base and the color layer and bonds the base and color layer together. The color layer includes at least one metal layer. A portion of the color layer corresponding to and located over the smooth region has a value for L* in a range from about 70.44 to about 72.44, a value for a* in a range from about −7.84 to about −6.84 and a value for b* in a range from about −8.57 to about −7.57 according to the Commission Internationale del'Eclairage LAB system. A surface-treating method for fabricating the colored casing is also provided.

### CROSS-REFERENCE TO RELATED APPLICATIONS

This application is related to co-pending U.S. patent applications (Attorney Docket Nos. US32592, US32593, US32594, US32595, US32597, US32598, US32599, US32560, US32600, US32601, US32602, US32603, US32604, US32605, US32606 and US32607), all entitled “COLORED DEVICE CASING AND SURFACE-TREATING METHOD FOR FABRICATING SAME”, invented by Chen et al. Such applications have the same inventors and assignee as the present application.

### BACKGROUND

1. Technical Field

The present disclosure relates to device casings, and particularly, to a casing colored by physical vapor deposition (PVD).

2. Description of Related Art

Colored device casings are usually formed by injection of colored plastic or spraying paint on a surface of a casing. However, neither method provides attractive metal texture. Furthermore, metal coating technology is complicated and difficult to control, so only a few colors are available for metal casings.

Therefore, it is desirable to provide a casing and a method for fabricating the casing which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present colored device casing and method for fabricating the casing. Moreover, in the drawings, like reference numerals designate corresponding parts throughout various views.

FIG. 1 is a schematic view of a mobile phone with a colored device casing according to an embodiment of the present disclosure.

FIG. 2 is a partial, cross-sectional view of the colored device casing shown in FIG. 1, showing, inter alia, a color layer.

FIG. 3 is a schematic diagram illustrating the L* value of the color layer shown in FIG. 2 according to the Commission Internationale del'Eclairage (CIE, International Commission on Illumination) LAB system.

FIG. 4 is a schematic diagram illustrating the a* value and the b* value of the color layer shown in FIG. 2 according to the CIE LAB system.

FIG. 5 is a flowchart illustrating an exemplary surface-treating method for fabricating a colored device casing, such as, for example, that of FIG. 1.

### DETAILED DESCRIPTION

Embodiments of the disclosure will now be described in detail with reference to the accompanying drawings.

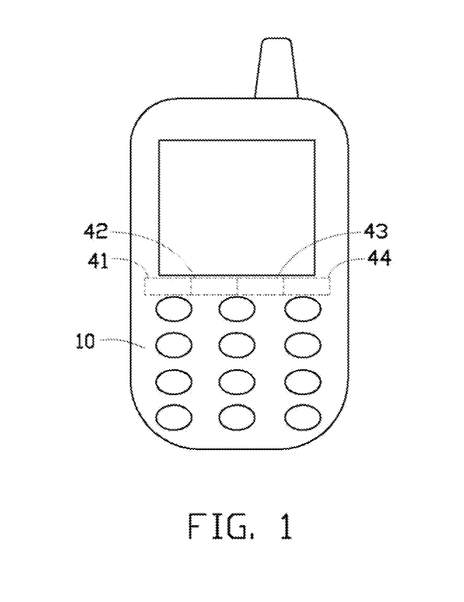

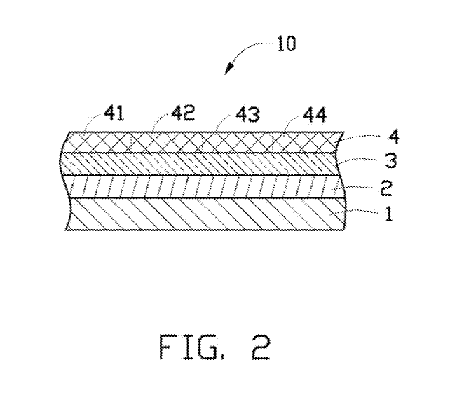

Referring to FIG. 1 and FIG. 2, an embodiment of the present disclosure provides a colored device casing 10 including a base 1, a bonding layer 2, a color layer 3 and an optional coating layer 4. The colored device casing 10 in the illustrating embodiment is a casing of a mobile phone, but is not limited thereto. The bonding layer 2 is located on and covers the base 1; the color layer 3 is located on and covers the bonding layer 2; and the coating layer 4 is located on and covers the color layer 3.

The base 1 can be metal such as steel, or can be ceramic or glass. The base 1 includes at least one surface to be coated, which includes at least one smooth region 11, at least one fine matte region 12, at least one rough matte region 13, at least one brushed finish region 14, or a combination thereof. The smooth region 11 is also referred to as a high-gloss or a mirror-like region. (The four regions should be included in the base 1, but it seems that they are included in the coating layer 4 in FIG. 2. So, I suggest you to delete the callout numbers and lead lines of the four regions shown in FIG. 2.)

The bonding layer 2 is formed between the base 1 and the color layer 3 for connection therebetween. Thus, the bonding layer 2 can include any material providing proper adhesion, such as chromium nitride (CrN).

The color layer 3 is configured to provide desired color, and includes one or more metal layers. In one embodiment, the color layer 3 includes a layer of an alloy of chromium (Cr) and aluminum (Al).

The coating layer 4 can include any appropriate material for protection, such material providing pollution resistance, electrical insulation, moisture resistance, or mechanical hardness.

The part of the colored device casing 10 including the base 1, the bonding layer 2 and the color layer 3 (i.e. excluding the coating layer 4) may exhibit a Vickers hardness equaling or exceeding 300 HV.

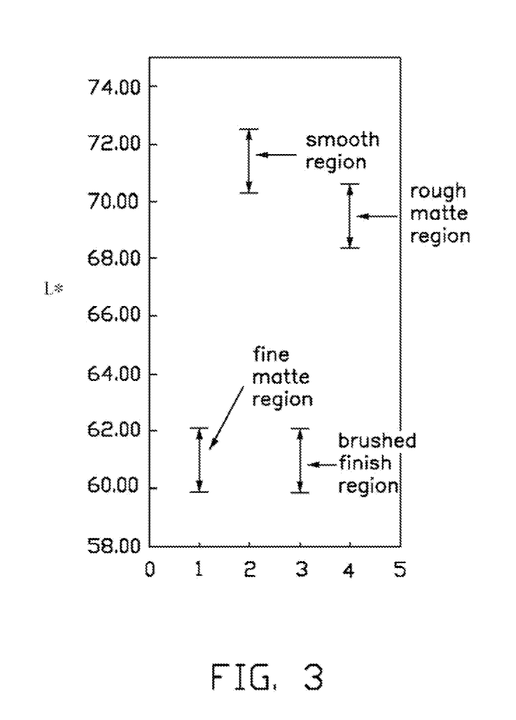

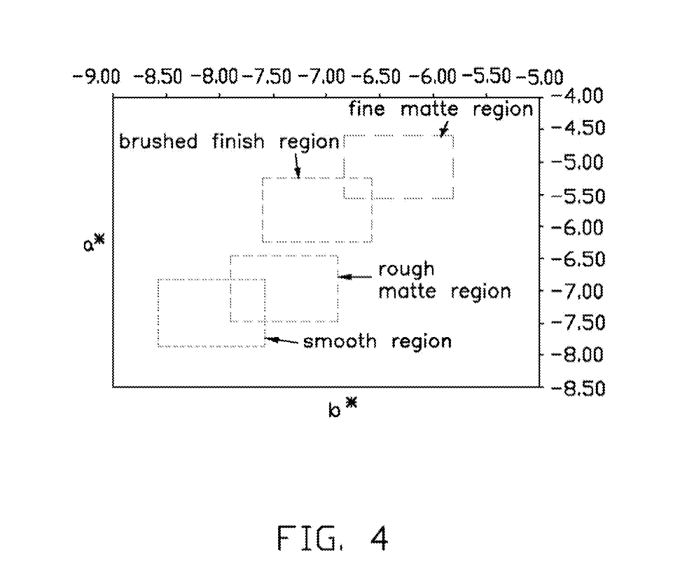

Referring to FIG. 3 and FIG. 4, portion of the color layer 3 corresponding to and located over the smooth region 11 of the base 1 has a value of L* between about 70.44 and about 72.44, a value of a* between about −7.84 and about −6.84 and a value of b* between about −8.57 and about −7.57 according to the Commission Internationale del'Eclairage (CIE) LAB system.

A portion of the color layer 3 corresponding to and located over the fine (inconsistent with FIGS. 3 to 5, the drawings of US32596 are uploaded) matte region 12 of the base 1 has a value of L* between about 60.04 and about 62.04, a value of a* between about −5.60 and about −4.60 and a value of b* between about −6.83 and about −5.83 according to the CIE LAB system.

A portion of the color layer 3 corresponding to and located over the rough (inconsistent with FIGS. 3 to 5, the drawings of US32596 are uploaded)) matte region 13 of the base 1 has a value of L* between about 68.51 and about 70.51, a value of a* between about −7.46 and about −6.46 and a value of b* between about −7.89 and about −6.89 according to the CIE LAB system.

A portion of the color layer 3 corresponding to and located over the brushed finish region 14 of the base 1 has a value of L* between about 59.87 and about 61.87, a value of a* between about −6.23 and about −5.23 and a value of b* between about −7.59 and about −6.59 according to the CIE LAB system.

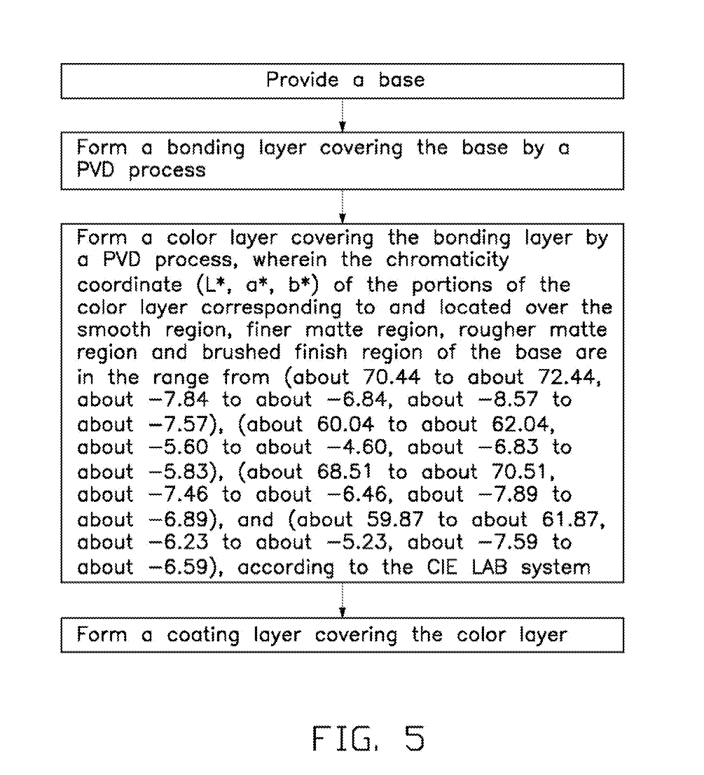

FIG. 5 shows an exemplary surface-treating method for fabricating a colored device casing such as, only for exemplary purpose, the colored device casing 10 of FIGS. 1 and 2. In the method, first, a base 1 is provided. The base 1 may undergo certain surface-treatments in advance as required. For instance, a pre-cleaning step may be carried out on the base 1, or the roughness of the base 1 may be enhanced to better support a subsequently formed bonding layer 2.

Subsequently, a bonding layer 2 is formed on a predetermined surface or region of the base 1. The bonding layer 2 may be formed by PVD, especially sputtering PVD. In one embodiment, argon plasma is excited at a flow rate from 27 to 33 standard cubic centimeters per minute (sccm) by a radio frequency (RF) generator to bombard a chromium target, and nitrogen gas is supplied at a flow rate from 108 to 132 sccm. As a result, chromium vapor is generated and combines with the nitrogen gas, and chromium nitride is obtained and deposits on the base 1.

Thereafter, a color layer 3 is formed on the bonding layer 2. This may include sputtering PVD with argon plasma excited by power supplies to bombard a chromium target and an aluminum target. In one embodiment, the power bombarding the chromium target is in a range from 2.7 to 3.3 kilowatts (kW), the power bombarding the aluminum target is in a range from 27 to 33 kW, the bias voltage is in a range from 180 to 220 volts (V), the process temperature is in a range from 180° C. to 220° C., the process time is in a range from 81 to 99 minutes, and the process pressure is in a range from 3.5 to 4.2 millitorr (mtorr). The power bombarding the chromium target and the aluminum target may be supplied by two power supplies, such as two RF generators or two medium frequency (MF) generators. The base 1 revolves around an axis outside the base 1 at 1.8 to 2.2 revolutions per minute (rpm), and rotates around its own axis at 7.2 to 8.8 rpm. This PVD process provides argon gas in a range from 54 to 66 sccm, and oxygen gas in a range from 162 to 198 sccm.

Accordingly, the colored device casing 10 of the present disclosure provides a desired color and metal texture. The chromaticity coordinate (L*, a*, b*) of the portions of the color layer 3 corresponding to and located over the smooth region 11, fine matte region 12, rough matte region 13 and brushed finish region 14 of the base 1 are in the range from (about 70.44 to about 72.44, about −7.84 to about −6.84, about −8.57 to about −7.57), (about 60.04 to about 62.04, about −5.60 to about −4.60, about −6.83 to about −5.83), (about 68.51 to about 70.51, about −7.46 to about −6.46, about −7.89 to about −6.89), and (about 59.87 to about 61.87, about −6.23 to about −5.23, about −7.59 to about −6.59), according to the CIE LAB system.

Furthermore, a coating layer 4 can be optionally formed on the color layer 3, according to any of various suitable techniques known in the art.

The colored device casing 10 of the present disclosure can be applied to any suitable object or device, such as a notebook or a personal digital assistant (PDA). For example, a mobile phone including the colored device casing 10 shown in FIG. 1 exhibits color and metal texture as described and thus provides an enhanced appearance.

It is to be understood, however, that even though numerous characteristics and advantages of various embodiments have been set forth in the foregoing description, together with details of the structures and functions of the embodiments, the disclosure is illustrative only; and that changes may be made in detail, especially in matters of arrangement of parts within the principles of the invention to the full extent indicated by the broad general meaning of the terms in which the appended claims are expressed.

What is claimed is:

1. A colored device casing, comprising:
a base, comprising a surface defining at least one smooth region;
a color layer located over the base, the color layer comprising chromium, wherein the color layer has a first portion corresponding to and located over the smooth region, and the first portion (do you agree? I totally agree with the edits you made) comprises a value for L* in a range from about 70.44 to about 72.44, a value for a* in a range from about −7.84 to about −6.84 and a value for b* in a range from about −8.57 to about −7.57 according to the Commission Internationale del'Eclairage (CIE) LAB system; and
a bonding layer located between the base and the color layer providing adhesion therebetween.

2. The colored device casing of claim 1, wherein the bonding layer comprises chromium nitride.

3. The colored device casing of claim 1, wherein the color layer comprises a layer of an alloy of chromium and aluminum, and is formed by utilizing a chromium target and an aluminum target in a physical vapor deposition (PVD) process.

4. The colored device casing of claim 1, wherein the base further defines at least one first matte region, the color layer has a second portion corresponding to and located over the first matte region, and the second portion comprises a value for L* in a range from about 60.04 to about 62.04, a value for a* in a range from about −5.60 to about −4.60, and a value for b* in a range from about −6.83 to about −5.83, according to the CIE LAB system.

5. The colored device casing of claim 1, wherein the base further defines at least one second matte region, the color layer has a third portion corresponding to and located over the second matte region, and the third portion comprises a value for L* in a range from about 68.51 to about 70.51, a value for a* in a range from about −7.46 to about −6.46, and a value for b* in a range from about −7.89 to about −6.89 according to the CIE LAB system.

6. The colored device casing of claim 1, wherein the base further defines at least one brushed finish region, the color layer has a fourth portion corresponding to and located over the brushed finish region, and the fourth portion comprises a value for L* in a range from about 59.87 to about 61.87, a value for a* in a range from about −6.23 to about −5.23, and a value for b* in a range from about −7.59 to about −6.59 according to the CIE LAB system.

7. The colored device casing of claim 1, wherein a Vickers hardness of the colored device casing equals or exceeds 300 HV.

8. The colored device casing of claim 1, further comprising a coating layer located over the color layer.

9. A surface-treating method for fabricating a colored device casing, the method comprising:
providing a base, comprising a surface defining at least one smooth region;
forming a bonding layer covering the base; and
forming a color layer covering the bonding layer by a physical vapor deposition (PVD) process, wherein the color layer has a first portion corresponding to and located over the smooth region, and the first portion comprises a value for L* in a range from about 70.44 to about 72.44, a value for a* in a range from about −7.84 to about −6.84 and a value for b* in a range from about −8.57 to about −7.57 according to the Commission Internationale del'Eclairage, (CIE) LAB system.

10. The method of claim 9, wherein the color layer is formed by bombarding a chromium target and an aluminum target in the PVD process, the power bombarding the chromium target is in a range from 2.7 to 3.3 kilowatts (kW), the power bombarding the aluminum target is in a range 27 to 33 kW.

11. The method of claim 9, wherein a bias voltage of the PVD process is from 180 to 220 volts (V).

12. The method of claim 9, wherein a process temperature of the PVD process is from 180° C. to 220° C.

13. The method of claim 9, wherein the PVD process lasts from 81 to 99 minutes.

14. The method of claim 9, wherein a process pressure of the PVD process is from 3.5 to 4.2 millitorr (mtorr).

15. The method of claim 9, wherein the PVD process comprises providing argon gas at 54 to 66 standard cubic centimeters per minute (sccm), and the PVD process comprises providing oxygen gas at 162 to 198 sccm.

16. The method of claim 9, wherein the base revolves around an axis outside the base at 1.8 to 2.2 revolutions per minute (rpm) in the PVD process, and the base rotates around its own axis at 7.2 to 8.8 rpm in the PVD process.

17. The method of claim 9, wherein the base further defines at least one first matte region, the color layer has a second portion corresponding to and located over the first matte region, and the second portion comprises a value for L* in a range from about 60.04 to about 62.04, a value for a* in a range from about −5.60 to about −4.60, and a value for b* in a range from about −6.83 to about −5.83, according to the CIE LAB system.

18. The method of claim 9, wherein the base further defines at least one second matte region, the color layer has a third portion corresponding to and located over the second matte region, and the third portion comprises a value for L* in a range from about 68.51 to about 70.51, a value for a* in a range from about −7.46 to about −6.46, and a value for b* in a range from about −7.89 to about −6.89 according to the CIE LAB system.

19. The method of claim 9, wherein the base further defines at least one brushed finish region, the color layer has a fourth portion corresponding to and located over the brushed finish region, and the fourth portion comprises a value for L* in a range from about 59.87 to about 61.87, a value for a* in a range from about −6.23 to about −5.23, and a value for b* in a range from about −7.59 to about −6.59 according to the CIE LAB system.

20. The method of claim 9, further comprising forming a coating layer on the color layer.
